(19) United States
(12) Patent Application Publication
(10) Pub. No.: US 2007/0057661 A1
(43) Pub. Date: Mar. 15, 2007

(54) Sampling apparatus and test apparatus

(75) Inventors: Nobuya Sato, Tokyo (JP); Takeshi Konno, Tokyo (JP); Satoshi Shiwa, Tokyo (JP); Hiroshi Miyamoto, Tokyo (JP)

Correspondence Address: OSHA LIANG L.L.P., 1221 MCKINNEY STREET, SUITE 2800, HOUSTON, TX, 77010, US

(73) Assignee: Advantest Corporation, Tokyo (JP)

(21) Appl. No.: 11/517,187

(22) Filed: Sep. 7, 2006

(30) Foreign Application Priority Data
Sep. 5, 2005 (JP) 2005-256736

(51) Int. Cl. G01R 13/14

(52) U.S. Cl. 324/76.15

(57) ABSTRACT

There is provided a sampling apparatus including a pulse generating circuit and a sampling circuit. The pulse generating circuit includes a step recovery diode and anode side and cathode side input terminals of the diode, and the sampling circuit includes a measured signal wire that inputs the measured signal, anode side and cathode side first wires of the step recovery diode that propagate the pulse signal generated from the pulse generating circuit, and a sampling section that includes a first diode for sampling, of which an anode is connected to the cathode side first wire side and a cathode is connected to the measured signal wire, and a second diode for sampling, of which an anode is connected to the measured signal wire and a cathode is connected to the anode side first wire side, in which the step recovery diode is formed on a semiconductor layer different from that on which the diodes for sampling are formed.

### CROSS REFERENCE TO RELATED APPLICATION

This is a continuation application of PCT/JP2006/316981 filed on Aug. 29, 2006 which claims priority from a Japanese Patent Application(s)

NO. 2005-256736 filed on Sep. 5, 2005, the contents of which are incorporated herein by reference.

### BACKGROUND

1. Field of the Invention

The present invention relates to a sampling apparatus and a test apparatus. More particularly, the present invention relates to a sampling apparatus and a test apparatus for sampling a measured signal with high frequency at high speed.

2. Related Art

In order to sample a measured signal from a measuring object, a sampling apparatus including a pulse generating circuit for generating pulses and a sampling circuit for sampling signals based on these pulses is known as disclosed, for example, in Japanese Patent Application Publication No. 2004-179912.

The pulse generating circuit generates a pulse signal having a steep edge based on a control signal to be input using a step recovery diode. Since the step recovery diode blocks a reverse current after a predetermined time when a reverse bias is applied to the step recovery diode by a control signal, such a pulse generating circuit causes sudden voltage variation to generate an edge of the pulse signal.

The sampling circuit samples a measured signal based on the pulse signal from the pulse generating circuit using a diode bridge.

Since a pulse signal having a steep edge can be generated by the pulse generating circuit, the above sampling apparatus is used, e.g., in a test apparatus to generate a sampling pulse for sampling a signal output from a device under test. In recent years, with speeding up of a device, it is required to generate a pulse signal having a steeper edge and a small pulse width at a small time interval, i.e., at a high frequency band. For example, in order to sample a measured signal at a speed not less than dozens of GHz, it is necessary that the pulse generating circuit generates a pulse signal with a pulse width of about 10 ps and the sampling circuit samples a measured signal based on the pulse signal.

Conventionally, a pulse generating circuit and a sampling circuit have been formed on a substrate different from each other, and have been connected to each other by wire bonding. However, such a configuration has a problem that a rise time increases by parasitic inductance of a bonding wire and thus it is difficult to generate a pulse signal with a pulse width of about 10 ps as described above.

### SUMMARY

Therefore, it is an object of some aspects of the present invention to provide a sampling apparatus and a test apparatus that can solve the foregoing problems. The above and other objects can be achieved by combinations described in the independent claims. The dependent claims define further advantageous and exemplary combinations of the present invention.

That is, according to the first aspect of the present invention, there is provided a sampling apparatus including a pulse generating circuit for generating a pulse signal based on a control signal to be input and a sampling circuit for sampling a measured signal based on the pulse signal, which are integrally formed on a substrate. The pulse generating circuit includes: a step recovery diode that blocks a reverse current to generate the pulse signal after a predetermined time from the application of a reverse voltage; and a control signal input port section that has an anode side input terminal and a cathode side input terminal for inputting the control signal to be applied to the step recovery diode, and the sampling circuit includes: a measured signal wire that inputs the measured signal from an outside; an anode side first wire and a cathode side first wire of the step recovery diode that propagate the pulse signal generated from the pulse generating circuit; and a sampling section that comprises a first diode for sampling, of which an anode is connected to the cathode side first wire side and a cathode is connected to the measured signal wire, and a second diode for sampling, of which an anode is connected to the measured signal wire and a cathode is connected to the anode side first wire side, and samples the measured signal according to the pulse signal, in which the step recovery diode is formed on a semiconductor layer different from that on which the first diode for sampling and the second diode for sampling are formed, these layers being layered on the substrate.

According to the second aspect of the present invention, there is provided a test apparatus that tests a device under test. The test apparatus includes: a pattern generator that generates a test pattern for the device under test; a waveform shaper that shapes the test pattern to generate a test signal to be supplied to the device under test; a signal output section that supplies the test signal to the device under test; a sampling apparatus that samples an output signal output from the device under test; and a deciding section that decides the good or bad of the device under test based on a signal sampled by the sampling apparatus. The sampling apparatus includes: a pulse generating circuit that inputs a control signal showing that the output signal should be sampled and generates a pulse signal based on this control signal; and a sampling circuit that samples the output signal based on the pulse signal. The pulse generating circuit includes: a step recovery diode that blocks a reverse current to generate the pulse signal after a predetermined time from the application of a reverse voltage; and a control signal input port section that has an anode side input terminal and a cathode side input terminal for inputting the control signal to be applied to the step recovery diode, and the sampling circuit includes: a measured signal wire that inputs the output signal; an anode side first wire and a cathode side first wire of the step recovery diode that propagate the pulse signal generated from the pulse generating circuit; and a sampling section that comprises a first diode for sampling, of which an anode is connected to the cathode side first wire side and a cathode is connected to the measured signal wire, and a second diode for sampling, of which an anode is connected to the measured signal wire and a cathode is connected to the anode side first wire side, and samples the measured signal according to the pulse signal, in which the step recovery diode is formed on a semiconductor layer different from that on which the first diode for sampling and the second diode for sampling are formed, these layers being layered on the substrate.

The summary does not necessarily describe all necessary features of the present invention. The present invention may also be a sub-combination of the features described above.

### BRIEF DESCRIPTION OF THE DRAWINGS

FIG. 1 is a view showing a configuration of a sampling apparatus 10 according to an embodiment of the present invention.

FIG. 2 is a view showing layered structure of a sampling apparatus 10 according to an embodiment of the present invention.

FIG. 3 is a view showing a configuration of a test apparatus 30 according to an embodiment of the present invention.

### DESCRIPTION OF EXEMPLARY EMBODIMENTS

The embodiments of the invention will now be described based on the preferred embodiments, which do not intend to limit the scope of the present invention, but just exemplify the invention. All of the features and the combinations thereof described in the embodiment are not necessarily essential to the invention.

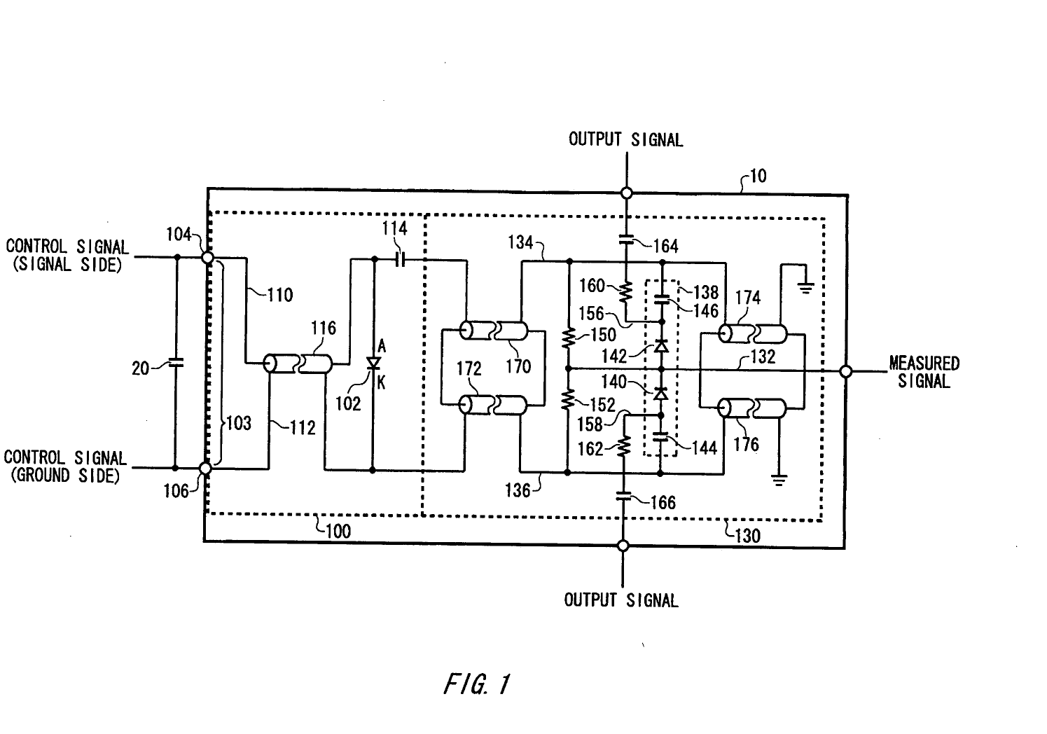

FIG. 1 is a view showing a configuration of a sampling apparatus 10 according to the present embodiment. The sampling apparatus 10 samples a measured signal to be input from an outside at a timing designated by a control signal, and outputs the sampled signal. The sampling apparatus 10 includes a pulse generating circuit 100 for generating a pulse signal based on a control signal to be input and a sampling circuit 130 for sampling the measured signal based on the pulse signal, and has a configuration made by integrally forming the pulse generating circuit 100 and the sampling circuit 130 on a substrate.

The pulse generating circuit 100 has a step recovery diode 102, a control signal input port section 103, an anode side wire 110, a cathode side wire 112, and a capacitor 114. After a predetermined time from the application of a reverse voltage, the step recovery diode 102 blocks a reverse current. The control signal input port section 103 has an anode side input terminal 104 and a cathode side input terminal 106 for inputting a control signal to be applied to the step recovery diode 102. In the present embodiment, one side of the anode side input terminal 104 and the cathode side input terminal 106 is connected to a ground side for the control signal, and the other side is connected to a signal side for the control signal. In FIG. 1 as an example, the cathode side input terminal 106 is connected to the ground side for the control signal. Moreover, the anode side input terminal 104 is connected to the signal side for the control signal and inputs a signal level of the control signal using the cathode side input terminal 106 as a standard. Alternatively, the anode side input terminal 104 may be connected to the ground side for the control signal and the cathode side input terminal 106 may be connected to the signal side for the control signal. As another configuration, the cathode side input terminal 106 may input a signal level obtained by reversing a signal level of the control signal input by the anode side input terminal 104. The capacitor 20 outside the sampling apparatus 10 is connected between the anode side input terminal 104 and the cathode side input terminal 106.

The anode side wire 110 is provided between the anode side input terminal 104 and an anode side output port of the pulse generating circuit 100, and an anode of the step recovery diode 102 is connected to a contact point located at a predetermined distance from the anode side input terminal 104. The cathode side wire 112 is provided between the cathode side input terminal 106 and a cathode side output port of the pulse generating circuit 100, and a cathode of the step recovery diode 102 is connected to the cathode side wire. The anode side wire 110 and the cathode side wire 112 may be formed on a substrate, for example, as a transmission channel 116 such as a microstrip transmission line.

In addition, in the present embodiment, since the anode side wire 110 in the anode side wire 110 and the cathode side wire 112 is connected to the anode side input terminal 104 on the signal side for the control signal, the anode side wire 110 functions as a second electric wiring on the signal side according to the present invention. On the other hand, since the cathode side wire 112 is connected to the cathode side input terminal 106 on the ground side for the control signal, the cathode side wire 112 functions as a second electric wiring on the ground side according to the present invention. Alternatively, when the anode side input terminal 104 is on the ground side and the cathode side input terminal 106 is on the signal side, the anode side wire 110 may function as the second electric wiring on the ground side and the cathode side wire 112 may function as the second electric wiring on the signal side respectively.

The capacitor 114 is provided between a contact point to which the step recovery diode 102 is connected on the anode side wire 110 and an anode side output port of the pulse generating circuit 100, and removes a direct current component and passes an alternating current component of the pulse signal generated from the step recovery diode 102, in order to propagate a pulse to the sampling circuit 130.

Next, an operation of the pulse generating circuit 100 will be described.

First, when performing sampling, a control signal falling from a positive voltage Vp[V] to a negative voltage Vn[V] is input into the anode side input terminal 104 using reference potential 0V of the cathode side input terminal 106 as a standard. This control signal is propagated to the anode of the step recovery diode 102 via the anode side wire 110. Then, a reverse voltage is applied to the anode of the step recovery diode 102. The step recovery diode 102 has low resistance and flows a reverse current for a predetermined time after the reverse voltage is applied to the step recovery diode 102. For this reason, anode side electric potential of the step recovery diode 102 does not become Vn for a predetermined time, but becomes a voltage Vn1[V] determined by resistance values of the anode side wire 110 and the step recovery diode 102. This Vn1 has a value, as an example, becoming |Vn−Vn1|>>|Vn1|.

Next, after a predetermined time is passed over, the step recovery diode 102 blocks a reverse current. As a result, an anode side voltage of the step recovery diode 102 rapidly becomes Vn[V], and a falling edge from Vn1[V] to Vn[V] is generated. This voltage waveform is propagated to the capacitor 20 via electric wiring between the anode side wire 110 and the anode side input terminal 104 and the capacitor 20. The capacitor 20 connected outside the sampling apparatus 10 reflects this voltage waveform and propagates a reversed voltage waveform to the anode side of the step recovery diode 102 via the anode side wire 110. In this way, in the anode side of the step recovery diode 102, a voltage waveform having a steeply falling edge from Vn1 to Vn and a voltage waveform having a steeply rising edge from |Vn1| to |Vn1| made by reversing this voltage waveform are synthesized as a pulse signal, and a falling pulse is generated. The width of this pulse signal is determined by means of a sum of length of the anode side wire 10 and the electric wiring between the anode side input terminal 104 and the capacitor 20.

The sampling circuit 130 has a measured signal wire 132, an anode side wire 134, a cathode side wire 136, a sampling section 138, a resistor 150, a resistor 152, a sampling signal output wire 158, a sampling signal output wire 156, a resistor 160, a resistor 162, a capacitor 164, and a capacitor 166. The measured signal wire 132 inputs a measured signal from an outside.

The anode side wire 134 and the cathode side wire 136 are examples of an anode side first wire and a cathode side first wire according to the present invention, and receive the pulse signal generated from the pulse generating circuit 100 from the pulse generating circuit 100 side ends of the sampling circuit 130 to propagate the signal. The anode side wire 134 is connected to the anode side wire 110 connected to the anode side of the step recovery diode 102. The anode side wire 134 has a transmission channel 170 and a transmission channel 174, and propagates the pulse signal output from the anode side end of the pulse generating circuit 100. The cathode side wire 136 is connected to the cathode side wire 112 connected to the cathode side of the step recovery diode 102. The cathode side wire 136 has a transmission channel 172 and a transmission channel 176, and propagates the signal output from the cathode side end of the pulse generating circuit 100. Here, the transmission channel 170 of the anode side wire 134 and the transmission channel 172 of the cathode side wire 136 are close to each other and are elongated in parallel. In this way, a rising pulse signal made by reversing a falling pulse signal propagated through the transmission channel 170 occurs on the transmission channel 172. Moreover, the transmission channel 170 and the transmission channel 172 according to the present embodiment are formed on a substrate as a wiring pattern having a substantially symmetric shape to a propagation direction of the pulse signal. In this way, the transmission channel 170 and the transmission channel 172 can appropriately generate and propagate the falling pulse signal and the rising pulse signal that is a pulse wave made by reversing the falling pulse signal.

In addition, in the present embodiment, since the anode side wire 134 in the anode side wire 134 and the cathode side wire 136 is connected to the anode side input terminal 104 on the signal side for the control signal, the anode side wire 134 functions as a signal side first wire according to the present invention. On the other hand, since the cathode side wire 136 is connected to the cathode side input terminal 106 on the ground side for the control signal, the cathode side wire 136 functions as a ground side first wire according to the present invention. Alternatively, when the anode side input terminal 104 is on the ground side and the cathode side input terminal 106 is on the signal side, the anode side wire 134 may function as the ground side first wire and the cathode side wire 136 may function as the signal side first wire respectively.

The sampling section 138 samples the measured signal to be input from the measured signal wire 132 according to the pulse signal to be input from the anode side wire 134 and the cathode side wire 136. The sampling section 138 includes a diode 140, a diode 142, a capacitor 144, and a capacitor 146. The diode 140 and the diode 142 are, e.g., Schottky diodes. A cathode of the diode 140 is connected to the measured signal wire 132 of which an anode is connected to the cathode side wire 136 side. Moreover, a cathode of the diode 142 is connected to the anode side wire 134 side of which an anode is connected to the measured signal wire 132. The capacitor 144 is connected between the cathode side wire 136 and an anode of the diode 140. The capacitor 146 is connected between the anode side wire 134 and the cathode of the diode 142. By the above configuration, the sampling section 138 outputs a voltage value obtained by sampling the measured signal at a timing of the pulse signal as a sampling signal via the sampling signal output wire 156 and the sampling signal output wire 158.

Alternatively, the sampling section 138 may have a configuration in which a measured signal is sampled by a diode bridge.

The resistor 150 and the resistor 152 terminate the measured signal propagating through the measured signal wire 132. The sampling signal output wire 158 is an example of a first sampling signal output wire according to the present invention, and one end thereof is connected to a first sampling signal output point that is a contact point provided on a wire between the diode 140 and the capacitor 144, and outputs a signal made by sampling the measured signal to the outside of the sampling apparatus 10. The sampling signal output wire 156 is an example of a second sampling signal output wire according to the present invention, and one end thereof is connected to a second sampling signal output point that is a contact point provided on a wire between the capacitor 146 and the diode 142, and outputs a signal made by sampling the measured signal to the outside of the sampling apparatus 10.

The resistor 160 and the resistor 162 are respectively provided on the sampling signal output wire 156 and the sampling signal output wire 158. The capacitor 164 is provided in series with the resistor 160 between the resistor 160 and an end for outputting a sampling signal from the sampling apparatus 10. The capacitor 166 is provided in series with the resistor 162 between the resistor 162 and the end for outputting a sampling signal from the sampling apparatus 10.

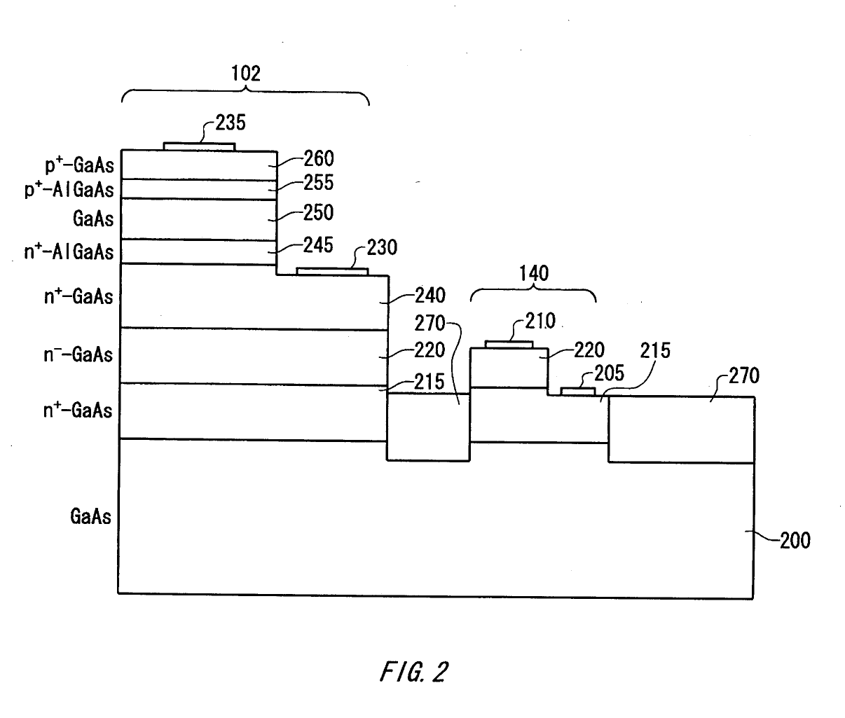

FIG. 2 is a view showing layered structure of the sampling apparatus 10 according to the present embodiment. The sampling apparatus 10 according to the present embodiment has a structure in which the pulse generating circuit 100 and the sampling circuit 130 are integrally formed on a substrate such as a GaAs substrate (a gallium arsenic substrate) 200. In this way, the sampling apparatus 10 can perform sampling, e.g., at a speed not less than dozens of GHz.

The sampling apparatus 10 according to the present embodiment is formed by means of a laminated substrate made by sequentially layering, on the GaAs substrate 200 as an example, an n+ type GaAs layer 215, an n− type GaAs layer 220, an n+ type GaAs layer 240, an n+ type AlGaAs layer 245, a GaAs layer 250, an n+ type AlGaAs layer 255, and a p+ type GaAs layer 260. Since the step recovery diode 102 has layered structure different from that of the diode 140 and the diode 142, the step recovery diode is formed on a semiconductor layer different from that of the diodes. Here, these semiconductor layers are layered on the GaAs substrate 200. In other words, the diode 140 and the diode 142 are formed by means of a semiconductor layer group consisting of a set of the n+ type GaAs layer 215 and the n− type GaAs layer 220. On the other hand, the step recovery diode 102 is formed by means of a semiconductor layer group consisting of a set of the n+ type GaAs layer 240, the n+ type AlGaAs layer 245, the GaAs layer 250, the n+ type AlGaAs layer 255, and the p+ type GaAs layer 260.

More specifically, in the diode 140 and the diode 142, a cathode 205 is provided on the n+ type GaAs layer 215 and an anode 210 is provided on the n− type GaAs layer 220. In this way, the diode 140 and the diode 142 have a structure in which the n+ type GaAs layer 215 and the n− type GaAs layer 220 are layered between the cathode 205 and the anode 210. By this structure, the diode 140 and the diode 142 function as a Schottky diode.

On the other hand, in the step recovery diode 102, a cathode 230 is provided on the n+ type GaAs layer 240 and an anode 235 is provided on the p+ type GaAs layer 260. In this way, the step recovery diode 102 has a structure made by sequentially layering the n+ type GaAs layer 240, the n+ type AlGaAs layer 245, the GaAs layer 250, the n+ type AlGaAs layer 255, and the p+ type GaAs layer 260 between the cathode 230 and the anode 235. By this structure, the step recovery diode 102 functions as a step recovery diode.

The step recovery diode 102 is insulated from the diode 140 and the diode 142 by means of an insulating material 270 that penetrates from a surface of the laminated substrate to the GaAs substrate 200. The step recovery diode 102 may be insulated from the diode 140 and the diode 142 by means of a penetrating groove reaching the GaAs substrate 200, in place of the insulating material 270. In addition, the diode 140, the diode 142, and the step recovery diode 102 may be connected to the wiring provided on the laminated substrate, by means of an electric conductor with an air bridge structure.

Alternatively, a semiconductor layer group on which the step recovery diode 102 is formed may be provided on an upper face side than a semiconductor layer group on which the diode 140 and the diode 142 are formed. Moreover, another semiconductor layer or a plurality of semiconductor layers may be provided between the semiconductor layer group on which the step recovery diode 102 is formed and the semiconductor layer groups on which the diode 140 and the diode 142 are formed.

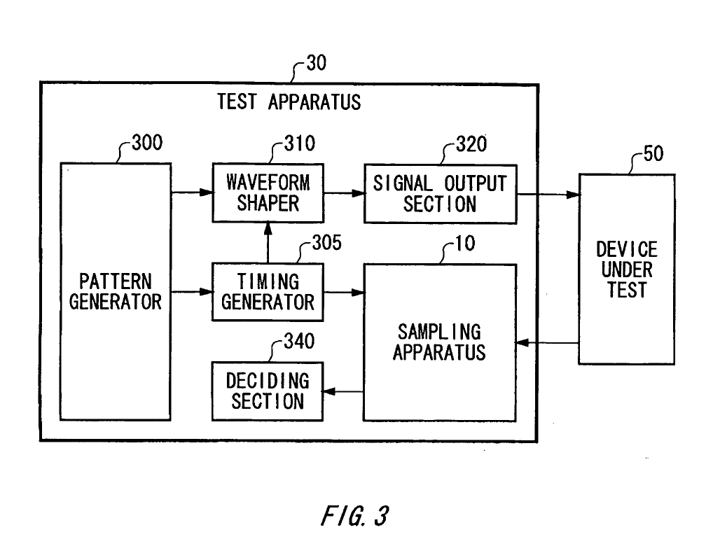

FIG. 3 is a view showing a configuration of a test apparatus 30 according to the present embodiment. The test apparatus 30 inputs a test signal based on a test pattern for testing the device under test 50 into the device under test 50, and decides the good or bad of the device under test 50 based on an output signal output from the device under test 50 according to the test signal.

The test apparatus 30 includes a pattern generator 300, a timing generator 305, a waveform shaper 310, a signal output section 320, a sampling apparatus 10, and a deciding section 340. The pattern generator 300 executes a series of commands of a test program designated by a user of the test apparatus 30, and generates a test pattern to be supplied to the device under test 50. The timing generator 305 generates a timing at which the test pattern should be output to the device under test 50 and a timing at which the output signal output from the device under test 50 should be sampled. The waveform shaper 310 receives the test pattern and shapes the pattern based on the timing generated from the timing generator 305, in order to generate a test signal to be supplied to the device under test 50. In other words, for example, the waveform shaper 310 outputs a signal waveform designated at a timing designated by the test pattern to the signal output section 320. The signal output section 320 supplies the test signal to the device under test 50.

The sampling apparatus 10 inputs and samples the output signal from the device under test 50. The sampling apparatus 10 includes the pulse generating circuit 100 and the sampling circuit 130 shown in FIG. 1. The pulse generating circuit 100 inputs a control signal, which is supplied from the timing generator 305, showing that the output signal should be sampled, and generates a pulse signal based on this control signal. The sampling circuit 130 samples the output signal based on this pulse signal. Since a configuration and a function of the sampling apparatus 10 shown in FIG. 3 are similar to those of the sampling apparatus 10 shown in FIGS. 1 and 2, the descriptions will be omitted. The deciding section 340 compares the sampled output signal with an expected value to decide the good or bad of the device under test 50.

According to the test apparatus 30 described above, it is possible to sample an output signal output from the device under test 50 at high frequency at high speed and judge the good or bad of the device under test 50.

Although the present invention has been described by way of an exemplary embodiment, it should be understood that those skilled in the art might make many changes and substitutions without departing from the spirit and the scope of the present invention. It is obvious from the definition of the appended claims that embodiments with such modifications also belong to the scope of the present invention.

What is claimed is:

1. A sampling apparatus comprising a pulse generating circuit for generating a pulse signal based on a control signal to be input and a sampling circuit for sampling a measured signal based on the pulse signal, which are integrally formed on a substrate,
the pulse generating circuit comprising:
a step recovery diode that blocks a reverse current to generate the pulse signal after a predetermined time from the application of a reverse voltage; and
a control signal input port section that has an anode side input terminal and a cathode side input terminal for inputting the control signal to be applied to the step recovery diode,
the sampling circuit comprising:
a measured signal wire that inputs the measured signal from an outside;
an anode side first wire and a cathode side first wire of the step recovery diode that propagate the pulse signal generated from the pulse generating circuit; and
a sampling section that comprises a first diode for sampling, of which an anode is connected to the cathode side first wire side and a cathode is connected to the measured signal wire, and a second diode for sampling, of which an anode is connected to the measured signal wire and a cathode is connected to the anode side first wire side, and samples the measured signal according to the pulse signal, and
wherein the step recovery diode is formed on a semiconductor layer different from that on which the first diode for sampling and the second diode for sampling are formed, these layers being layered on the substrate.

2. The sampling apparatus as claimed in claim 1, wherein
the substrate is a GaAs (gallium arsenic) substrate,
first n+ type GaAs layer and n− type GaAs layer are layered between the cathode and the anode of the first diode for sampling and the second diode for sampling, and
second n+ type GaAs layer, n+ type AlGaAs layer, GaAs layer, p+ type AlGaAs layer, and p+ type GaAs layer are sequentially layered between the cathode and the anode of the step recovery diode.

3. The sampling apparatus as claimed in claim 1, further comprising:
a first capacitor for sampling that is connected between the cathode side first wire and the anode of the first diode for sampling; and
the second capacitor for sampling that is connected between the anode side first wire and the cathode of the second diode for sampling.

4. The sampling apparatus as claimed in claim 3, wherein the anode side first wire and the cathode side first wire are formed on the substrate as a wiring pattern having a substantially symmetric shape to a propagation direction of the pulse signal.

5. A test apparatus that tests a device under test, comprising:
a pattern generator that generates a test pattern for the device under test;
a waveform shaper that shapes the test pattern to generate a test signal to be supplied to the device under test;
a signal output section that supplies the test signal to the device under test;
a sampling apparatus that samples an output signal output from the device under test; and
a deciding section that decides the good or bad of the device under test based on a signal sampled by the sampling apparatus,
the sampling apparatus comprising:
a pulse generating circuit that inputs a control signal showing that the output signal should be sampled and generates a pulse signal based on this control signal; and
a sampling circuit that samples the output signal based on the pulse signal,
the pulse generating circuit comprising:
a step recovery diode that blocks a reverse current to generate the pulse signal after a predetermined time from the application of a reverse voltage; and
a control signal input port section that has an anode side input terminal and a cathode side input terminal for inputting the control signal to be applied to the step recovery diode,
the sampling circuit comprising:
a measured signal wire that inputs the output signal;
an anode side first wire and a cathode side first wire of the step recovery diode that propagate the pulse signal generated from the pulse generating circuit; and
a sampling section that comprises a first diode for sampling, of which an anode is connected to the cathode side first wire side and a cathode is connected to the measured signal wire, and a second diode for sampling, of which an anode is connected to the measured signal wire and a cathode is connected to the anode side first wire side, and samples the measured signal according to the pulse signal, and
wherein the step recovery diode is formed on a semiconductor layer different from that on which the first diode for sampling and the second diode for sampling are formed, these layers being layered on the substrate.
